(19) United States
(12) Patent Application Publication
(10) Pub. No.: US 2009/0301548 A1
(43) Pub. Date: Dec. 10, 2009

(54) Condensing Generator

(76) Inventor: Cunyi Wang, Xian (CN)

Correspondence Address: Locke Lord Bissell & Liddell LLP;Attn: Michael Ritchie, Docketing, 2200 Ross Avenue, Suite # 2200, DALLAS, TX, 75201-6776, US

(21) Appl. No.: 12/227,445

(22) PCT Filed: May 16, 2007
(86) PCT No.: PCT/CN2007/001583

§ 371 Date: Jul. 24, 2009

(30) Foreign Application Priority Data
May 19, 2006 (CN) 200610084349.3

(51) Int. Cl. H01L 31/058; F03D 9/00

(52) U.S. Cl. 136/248; 290/55

(57) ABSTRACT

A condensing generator comprises a condensing photovoltaic generating system, a cooling and radiating system, an automatic sun-tracking machine and a wind power generator. The condensing photovoltaic generating system includes a group of collecting mirrors with a wind-sheltering mechanism, a uniform light generator, an object carrier and a collecting carrier. The object carrier is movably connected to the automatic sun-tracking machine, and the collecting carrier is immovably connected to the object carrier. The uniform light generator includes a condensing battery base with a cavity and condensing photovoltaic batteries supported by the condensing battery base. The cooling and radiating system has a fluid radiator which is communicated with the cavity of the condensing battery base through flexible connecting pipes using a radiator's interface.

### FIELD OF THE INVENTION

The present invention relates to the field of solar power generation, specifically to a high effective and low cost light collecting superconductive solar power generator, it is hereinafter shorted as a highly efficient light collecting generator.

### BACKGROUND OF THE INVENTION

In the current solar photovoltaic power generation industry, generally the photovoltaic cells are fixed; the price for the photovoltaic cell are calculated at per watt peak which refers to the generated electricity power when meeting two conditions: one is that the sunlight is vertical to the photovoltaic cell, the other is that the light intensity is the standard sunlight irradiation, so the actual power generated can't reach the nominal power peak value of the photovoltaic cell. Furthermore, many researchers have done a lot of experiments of the automatically tracking sunlight power generation, and these experiments demonstrate that the automatically tracking sunlight power generation increases the output power by 40% compared with that without sun-tracking machine. However, since the sun-tracking machine used is expensive, this counteracts most of the benefit of the increased power generation. Some researchers have studied the power generation system by combining wind power and solar power generation; however, the photovoltaic cells used are fixed and didn't organically combine the wind power and solar power generation. Although pure light collecting solar power generation can save the number of photovoltaic cells, except for adding optical devices and an automatic sun-tracking machine, there are some problems like the heat radiation of photovoltaic cells and how to sheltering the strong wind etc., so the composite cost is still very high.

To solve the problems described above, the applicant of the present invention has provided several solutions, however, these solutions still have the following main problems: (1) the photovoltaic cells are immersed in transparent liquid medium, since the convective heat transfer of the liquid is very quick, the temperature of the photovoltaic cells is higher than the temperature of environment, so the photoelectric conversion efficiency can be largely increased by greatly decreasing the temperature; (2) the single transparent cover tube provided can be only constructed as single liquid concave mirror, and it is difficult to turn the condensed light to be uniform, so that it is difficult to increase the efficiency by collecting light; (3) during using the day-night temperature difference, the covering-uncovering member provided is heavy and expensive, this will not facilitate to cooperate with a heat pump to realize the combined heat and power generation; (4) only the lower cooling device is provided, and the upper cooling and heating chamber isn't provided, so this can't reach the effect that phase transformation occurs in the heating tube without pump cycling, so as not to facilitate the cooperation with the heat pump and, nor to facilitate heat absorption from the environment by the heat pump to heat when there is no sunlight; (5) the concept of hydraulic shock resist is not suggested, which is a method of shock resist with high efficiency and low cost; (6) the concept of wind sheltering plate is not suggested, even more the wind sheltering plate is not defined.

### SUMMARY OF THE INVENTION

The present invention attempts to solve the problems described above, and provides a very high efficiency and low cost device which has a very high multiple for light collecting and with the operating temperature much lower than the environment temperature. It makes the collected light intensity even at the lowest cost in order to obtain a very high efficiency of power generation; at the same time, it also can automatically shelter strong wind and resist shock so as to obtain the largest safety coefficient; it makes the electricity and heat generation doubled to get the combined heat and power generation.

The present invention is realized by the following technical solutions.

A highly efficient light collecting and superconductive generator (condensing generator), hereinafter shorted as a highly efficient light collecting generator, comprising a light collecting photovoltaic power generation system, a cooling and radiating system, an automatic sun-tracking machine, and further comprising a wind power generator, in which the light collecting photovoltaic power generation system, hereinafter shorted as a light collecting generation system, comprises a group of light collecting mirrors with a wind-sheltering mechanism for meeting an emergency, a uniform light generator, an object carrier, and a collecting carrier, wherein:

A. the object carrier is movably connected to the automatic sun-tracking machine, the collecting carrier is fixedly connected to the object carrier, the group of light collecting mirrors with an wind-sheltering mechanism is connected to the collecting carrier or object carrier in the following two ways: one is a movable connection, i.e. hinging connection; the other is a fixed connection; the uniform light generator, which is located in or near to the public focus line/area/point of the light collecting mirror during operation, is supported by and connected to the collecting carrier; all the lighting planes vertical to the main axis of the respective light collecting mirror are vertical or constantly approximately vertical to sunlight;

B. the group of light collecting mirror hinged with a wind-sheltering mechanism consists of a light collecting mirror unit which is single light collecting mirror or double light collecting mirrors; the single light collecting mirror unit, hereinafter shorted as a single mirror unit, comprises a light collecting mirror installed in a mirror framework and a restoring spring, a stop and a hinge shaft, and further comprises a wind-sheltering plate and a shock resist; in which the mirror framework is hinged to the collecting carrier via the hinge shaft; the restoring spring, at the two ends, is connected to the collecting carrier and the light collecting mirror, respectively, so that the stop constantly keeping the hinged light collecting mirror in a correct operating position is located between the mirror framework and the collecting carrier;

the wind-sheltering plate is a plate-like member or a flat box member which can rotate the light collecting mirror to shelter the wind so as to suffer minimal wind resistance in case of a harmful strong wind;

C. a hinged double light collecting mirror unit, hereinafter shorted as a double mirror unit, consists of a main light collecting mirror and an auxiliary light collecting mirror, in which the main mirror is the said single light collecting mirror connected to the collecting carrier, and the auxiliary light collecting mirror is carried by the main light collecting mirror and comprises a light collecting mirror installed in an auxiliary mirror framework, a restoring spring, and a hinge shaft; the auxiliary light collecting mirror further comprises a shock resist, the auxiliary mirror framework is connected to the main mirror framework by the hinge shaft, the restoring spring, at both ends, is connected to the main mirror and the auxiliary mirror framework, respectively;

D. the uniform light generator comprises a light collecting cell seat, a light collecting photovoltaic cells, and a connection circuit, and further comprises a uniform light element and a transparent cover tube, the light collecting cell seat has a cavity; the light collecting photovoltaic cell, hereinafter shorted as a light collecting cell, is carried by a wall of the of the light collecting cell; and the respective light collecting cell sheet is connected by the connection circuit to form a photovoltaic generating body which is surrounded by the transparent cover tube; the photovoltaic generating body forms a vacuum layer or a negative pressure layer between the photovoltaic generating body and the transparent cover tube; the uniform light generator without the uniform light element is a photovoltaic power generating body, or called photovoltaic power generation tube;

E. the light collecting mirror with the wind-sheltering mechanism is a reflection light collecting mirror or a Fresnel lens; the sunlight directly irradiates on the light collecting cells through the light collecting mirror, or the sunlight passes through the uniform light element and then irradiates on the light collecting cells;

F. the cooling and radiating system comprises a fluid radiator which communicates with the cavity of the light collecting cell seat via a flexibly bendable connecting pipe through its port, the position of the port is higher than the highest position to which the light collecting cell seat can reach; the fluid radiator is a liquid radiator, or a condensation section of a heating tube formed by itself and the cavity of the light collecting cell seat and the flexible connecting tube; in this case, the cavity of the light collecting cell seat is a evaporative section of the heating tube, the flexible tube is a heat isolation section of the heating tube, with operation medium cycles therein; the light collecting cell seat and the flexible connection tube are filled with liquid in the case that the fluid radiator is a liquid radiator.

According to one aspect of the present application, the cooling and radiating system further comprises a cooler for cold source; the cooler for cold source is either an upper cold source which is located higher than the position of the cold source of the condensation section of the heating tube, or a lower cold source which is located lower than the position of the cold source of the condensation section of the heating tube; the cold source is a refrigerator which reserve cold energy; the refrigerator is a day-night temperature difference refrigerator, an ordinary heat pump refrigerator, or an adsorption refrigerator, a Peltier refrigerator, a magnetic refrigerator, a metal hydride refrigerator, an absorbing refrigerator, or an integrated refrigerator.

According to one aspect of the present application, the highly efficient light collecting and superconductive generator according to claim 1, wherein the day-night temperature difference refrigerator is either an upper day-night temperature difference refrigerator or a lower day-night temperature difference refrigerator; the upper day-night temperature difference refrigerator comprises an upper cooling and heating chamber, an operation medium and a covering-uncovering member, the covering-uncovering member is located around the upper cooling and heating chamber and is carried by the later one or by the hollow column which includes the cooling and heating chamber, or by a framework of the wind power generator; the lower day-night temperature difference cooler includes a lower cooling and heating chamber, operation medium therein and a covering-uncovering member, and further comprises an absorbing and transmitting device; the covering-uncovering member is located around the lower cooling and heating chamber taken as the carrier or a hollow column containing the cooling and heating chamber as the carrier, or, optionally with an associated framework of the wind power generator is taken as the carrier; in the case that the heating tube is not a non-gravity heating tube, an absorbing and transmitting device is needed as a heat absorbing and transmitting device which lower section extends into the medium of the lower cooling and heating chamber, and which upper section extends into the medium of the condensation section of the heating tube; preferably the absorbing and transmitting device is a heat conductive element made of high heat conductive material, or a medium flowing pipe which is either an open loop or a close loop; a driven power source of medium flowing pipe or switch circuit of the driven power source is supplied by the solar cell which either is or is not synchronous with the strong or weak to the density of the sunlight, or by another outer power source;

the ordinary heat pump cooler comprises a heat pump, a upper cooling and heating chamber, operation medium therein and a covering-uncovering member, the evaporative cooling section of the heat pump is located within medium of the upper cooling and heating chamber, a compress heat producing section of the heat pump is located within the heat consumption device which is outside the cooling and heating chamber, the associated covering-uncovering member is located around the upper cooling and heating chamber taken as carrier; optionally the framework of the wind power generator containing the upper cooling and heating chamber or the hollow column is taken as carrier; a part of the condensation section of the heating tube extents into medium of the upper cooling and heating chamber to form a gravity heating tube, or extents into medium of the lower cooling and heating chamber to form non-gravity heating tube; the evaporative cooling section of the heat pump directly extends into medium of the condensation section of the heat pump, or extends into medium of the lower cooling and heating chamber;

the evaporator of the adsorption cooler is located within medium of the lower cooling and heating chamber, or is the lower cooling and heating chamber; an adsorption-desorbing cavity thereof is located under sunlight, or is flat box wind-sheltering member of the single-member light collecting mirror, one end at the heat radiator is connected to the adsorption-desorbing cavity, the other end is connected to the evaporator, the absorbing-transmitting device is located between the lower cooling and heating chamber and the condensation chamber of the heating tube to form connection for exchanging heat; the covering-uncovering member is installed around the lower cooling and heating chamber;

the Peltier cooling device comprises a heat absorbing end and a heat radiation end of a circuit made of two different kinds of materials connected according to Peltier effect, with the electric current flowing in the direction prescribed by the Peltier cooling effect, in which the heat absorbing end is inserted into the condensation chamber, the power generation tube or the upper cooling and heating chamber, and the heat radiating end is either inserted into the heat consumption device or into somewhere easy to radiate; the power source of the Peltier cooling device comes from residual current supplied by the light collecting power generator cell, or from residual current supplied by the wind power generator, or from other outer power source;

the integrated cooling is to use two or more than two cooling approaches at the same time.

According to one aspect of the present application, the highly efficient light collecting and superconductive generator according to claim 2, wherein the cooling and heating chamber and the condensation chamber of the heating tube is an internal cavity of a hollow column or an internal cavity of the framework of the wind power generator; the internal cavity is partitioned into three chambers consisting of an upper cooling and heating chamber, a lower cooling and heating chamber and a condensation chamber by partitions, or the internal cavity is partitioned into two chambers consisting of an upper cooling and heating chamber and a heating tube condensation chamber by a partition, all these cooling and heating chambers are called inner cooling and heating chamber, hereinafter shorted as cooling and heating chamber, and the other cooling and heating chambers except the above chambers are called outer cooling and heating chambers; a covering-uncovering member which is installed around the cooling and heating chamber and condensation chamber is an isolating-adsorbing-type covering-uncovering member, a rotary-vane-type covering-uncovering member, a rolling covering-uncovering member, or a push-pull covering-uncovering member;

the isolating-adsorbing-type covering-uncovering member comprises an isolating-adsorbing plate, a heat isolation sheet, an overturning ring, a flexibly elastic transmitting force element which is hereinafter shorted as a flexibly elastic element, and a driving assembly, or further comprises a horizontal-vertical plate, or more further comprises a signal generator and a sensor; the isolating-adsorbing plate is formed by the combination of an isolating-adsorbing support plate and a heat isolation layer, the isolating-adsorbing plate either prevents the heat transmission between the wall of the upper or lower cooling and heating chamber or the wall of the condensation chamber and the environment, or becomes a radiation sheet for the upper or lower cooling and heating chamber or condensation chamber, or becomes a plate product of heat absorbing sheet for absorbing heat from the environment to improve the efficiency of the heat pump when the temperature of an evaporative cooling end of the heat pump is very low; an opening for supporting, extending and carrying the heat absorbing sheet is provided at the front surface of the isolating-adsorbing support plate; and ventilated windows are provided at both sides of the isolating-adsorbing support plate; the back surface of the isolating-adsorbing plate is made in such a shape that allows it to engage with the wall of the cooling and heating chamber or the wall of the condensation chamber; on one hand, the isolating-adsorbing plate engages and disengages with the wall of the cooling and heating chamber or the wall of the condensation chamber by the indirectly movable connection, preferably hinged connection, between the horizontal-vertical plate and the wall of the cooling and heating chamber or the wall of the condensation chamber, or by directly hinging on he wall of the cooling and heating chamber or the wall of the condensation chamber, and the horizontal-vertical plate is a transition plate hinged on the wall of cooling and heating chamber or the wall of the condensation chamber; on the other hand, the isolating-adsorbing plate is connected to the overturning ring via the flexibly elastic element or flexible transmitting element; the overturning ring is carried by either the hollow column or the framework of the wind power generator and rotating around the latter, or is directly connected or indirectly via a force transmitting device connected to the driving assembly to transmit a torque; the driving assembly is controlled by either the signal controller or the sensor;

the rotary-vane-type covering-uncovering member comprises a heat isolation support plate, a heat isolation sheet, a flexibly elastic element, a force transmission element, a guider, and a driving assembly, and further comprises a signal controller and a sensor, and it can more further comprises a horizontal-vertical plate, in which the heat support plate when the heat isolation sheet is connected and spread is called heat isolation vane; on one hand, the heat isolation support plate is directly hinged on or indirectly hinged on via the horizontal-vertical plate hinged on the wall of the cooling and heating chamber or the wall of the of the condensation chamber; on the other hand, the heat isolation vane is connected to the guider by the flexibly elastic element; the said guider, via the inner circle, is movably connected to the hollow column or the framework of the wind power generator, and is carried by and rotates around the latter; the guider is directly connected or indirectly connected via the force transmission element to the driving assembly to transmit a torque; the driving assembly is controlled by either the signal controller or the sensor;

the rolling covering-uncovering member consists of two types:

the first type comprises a heat isolation layer, a primary roller, an auxiliary roller, an auxiliary column and a driving assembly, and further comprising a flexibly elastic element and a signal controller, in which the primary roller is movably connected to and thereby allow the primary roller to rotate around the wall of the cooling and heating chamber or the wall of the condensation chamber; the auxiliary column is parallel to the axis of the cooling and heating chamber or the axis of storing or radiating chamber, the auxiliary roller which rotates around the auxiliary column is nested on the circumference of the auxiliary column; one end of the heat isolation layer is fixed on the circumference of the primary roller after winding the primary roller, optionally one end of the heat isolation layer is connected to one end of the flexible elastic element, then the other end of the flexible elastic element is fixedly connected to the primary roller; the other end of the heat isolation layer winds around and then is fixedly connected on the circumference of the auxiliary roller; both the primary roller and the auxiliary roller are fixedly connected to force transmission pulleys to form connection with the driving assembly for transmitting a torque; the driving assembly is connected to and controlled by the signal controller;

the second type of the rolling covering-uncovering member comprises a heat isolation layer, an auxiliary shaft, an auxiliary roller, a flexibly elastic member, a driving assembly, and a signal controller; wherein one end (side) of the heat isolation layer is connected to the flexibly elastic member which the other end winds around and then is fixedly connected to the wall of the cooling and heating chamber or the wall of the condensation chamber, the other end (side) of heat isolation layer is either fixedly connected to the wall of the auxiliary roller, or is connected to the flexibly elastic member, winding around the auxiliary roller, and is then fixedly connected to the wall thereof; the auxiliary roller that rotates around the auxiliary column is movably nested on the wall of the auxiliary column and fixedly connected to a force transmission wheel which is constructed to connect with the said driving assembly to transmit a torque; the driving assembly is connected to the signal controller;

the push-pull covering-uncovering member comprises a plurality of heat isolation petals, a pull assembly, a roller or rotating drum, and a driving assembly; it further comprises an action signal generator, in which the said pull assembly enables the heat isolation petals to move periodically under action of the driving assembly; the said pull assembly comprises an inner mounting, a spring, a flexible transmission element, an outer mounting, and a pulley, in which one end of the spring is connected to the heat isolation petal, and the other end thereof is connected to the inner mounting; one end of the said flexible transmission element is connected to the heat isolation petal, the other end thereof winds the pulley installed in the outer mounting and then is directly or indirectly connected to the roller or rotating drum; or the pulls assembly is construed as another combination, in which one end of spring is connected to the outer mounting, and the other end thereof is connected to the heat isolation petal, one end of said flexible transmission element is connected to the heat isolation petal, and the other end thereof winds the pulley installed in the inner mounting, and then is directly or indirectly fixedly connected to the roller; the roller is constructed to connect with the driving assembly to transfer the torque; the driving assembly and the signal generator is either an integrated structure or a separated structure in communication with each other by the signal emitted by the signal generator; the inner mounting is the member nearest to the storing and radiating chamber, and the outer mounting is the member relatively further to storing and radiating chamber.

According to one aspect of the present application, the axis or the extended line of the axis of the hinge shaft of the single light collecting mirror, or of the hinge shaft of the main light collecting mirror of the double light collecting mirrors divides the said light collecting mirrors into two unequal portions; the sheltering plate of the single light collecting mirror or the auxiliary light collecting mirror of the double light collecting mirrors is hinged in the side of the smaller portion so as to allow the sheltering plate or the auxiliary light collecting mirror to keep in a correct operation position so as to install the stop and the restoring spring near the respective hinge shaft, the sheltering plate or the auxiliary light collecting mirror is rotated in one direction to shelter the wind,

According to one aspect of the present application, the shock resist is a hydraulic shock resist, a cavity shock resist, or a elastic force shock resist; the hydraulic shock resist is installed between a hinging member and a hinged member, the hinge between both is a shaft fixedly connected to the hinging member, or is a spindle fixedly connected to the hinged member; the hydraulic shock resist comprises a cavity shell, a baffle, a valve and a valve shell, in which the baffle is fixedly connected to the shaft fixedly connected to the hinging member; the cavity shell passes through the shaft to connect with the shaft in rest seal manner and receives a part of the baffle and the valve shell, and the cavity shell is connected with the part in movable seal manner; the valve is movably connected to and is carried by the valve shell; the space between the valve and the baffle is increased or reduced, the valve shell is fixedly connected to the hinged member so as to form movable seal with the shaft; operation medium is filled among the cavity shell, the shaft and the valve shell;

optionally all the rest and moving members except the hinging members and hinged member are interchanged, i.e., the hinge shaft is fixedly connected to the hinged member and movably connected to the hinging member, in this case, the valve shell carrying the valve is fixedly connected to the hinging member as the baffle is fixedly connected to the spindle, the rest cavity shell which previously receives a part of the baffle and the valve shell becomes a movable shell and is fixedly connected to the spindle to form a rest seal, and a movable seal is still formed between the cavity shell and valve shell; operation medium is filled among the movable cavity shell, the spindle and the valve shell;

the cavity shock resist comprises a hollow cylinder and a piston cooperating with the cylinder; there are either small holes in the hollow cylinder or piston, or there is a clearance between contacting surfaces of piston and hollow cylinder; the center line of the torque which forces the piston to move within the hollow cylinder is an axis of the shaft of the single or double light collecting mirror; in the case of the single light collecting mirror, when the piston is fixedly connected to the framework of the light collecting mirror, the wall of the hollow cylinder is fixedly connected to the collecting carrier, or vice versa, i.e. when the piston is fixedly connected to the collecting carrier, the wall of the hollow cylinder is fixedly connected to the framework of the light collecting mirror; the cavity shock resist which rotates around the hinge shaft of the wind sheltering plate is installed in a manner that the hollow cylinder is fixedly connected to the wind sheltering plate when the piston is fixedly connected to the framework of the light collecting mirror, or vice versa, i.e. when the hollow cylinder is fixedly connected to the framework of the light collecting mirror, the piston is fixedly connected to the wind sheltering plate; in the case of the double light collecting mirror, the installment for the cavity shock resist which rotates around the hinge shaft of the main light collecting mirror is the same as the installment of the single light collecting mirror; the installment for the cavity shock resist which rotates around the hinge shaft of the auxiliary light collecting mirror is the same as the installment for the cavity shock resist around the hinge shaft of the wind sheltering plate of the single light collecting mirror;

the elastic force shock resist is installed between the hinged member and the hinging member.

According to one aspect of the present application, the said uniform light device is a liquid lens or a solid lens located between the light collecting mirror and the light collecting cells, wherein the said liquid lens is a lens which consists of an inner transparent cover tube which surrounds the photovoltaic cells, an outer transparent cover tube and transparent medium between the cover tubes, and turns the collected light beam into an even intensity light beam, the layer between the inner transparent cover tube and the photovoltaic cells is a vacuum or negative pressure layer; the said solid lens is a cylindrical lens corresponding to a line focusing light collecting mirror and turning the focused light beam into a intensity even light beam; or the solid lens is a lens corresponding to the point focusing light collecting mirror, and turns the focused light beam into an even intensity light beam.

According to one aspect of the present application, the liquid lens or solid lens is a lens corresponding to one of the line/area/point focusing light collecting mirror; the transparent cover tube corresponding to the point focusing light collecting mirror is called point light collecting cover tube that is in a form of group concave or group convex, and that along the length of the shell, at the inner or outer cover tube shell, or at both shells, there is one or two or three or four or five or six or seven or eight or nine rows of concave or convex hulls distributed, through which the sunlight passes during operation, with each row having a series of concave or convex hulls through which the focused light beam passes during operation; the transparent cover tube corresponding to the line focusing light collecting mirror is called line light collecting cover tube that is in a form of indentation or convex puncheon, and that along the length of the shell, at the inner or outer cover tube shell, or at both shells there is one or two or three or four or five or six or seven or eight or nine rows of indentations or convex puncheons distributed, through which the focused light beam actually passes during operation and the cross section thereof is any curve surface selected.

According to one aspect of the present application, the electromagnetic driving assembly fixedly connected to the wind-sheltering mechanism of the light collecting mirror comprises a wind sensor of an electric device, and further comprises a controller with a self-protection circuit against strong wind, the wind sensor, the controller and the electric device is in electromagnetic communication with each other, the electric device is connected to the object carrier of the automatic sun-tracking machine to transmit a torque.

### BRIEF DESCRIPTION OF THE DRAWINGS

FIG. 1 is a front view of the first embodiment according to the present invention;

FIG. 2 is a left side view of FIG. 1;

FIG. 3 shows the second embodiment according to the present invention, i.e., the cooling system with the flat box wind-sheltering plate and an absorbing cooler combined;

FIG. 4 shows the third embodiment according to the present invention, i.e. the integrated heat radiation system which combines open heat exchanger, heat conduction and internal and external cooling source;

FIG. 5 shows an alternative light collecting mirror with a hydraulic shock resist in case of the eastern wind according to the present invention;

FIG. 6 shows an alternative point light collecting cover tube for a uniform light power generation tube according to the present invention;

FIG. 7 is a cross-section view of FIG. 6;

FIG. 8 shows an alternative cavity-type shock resist according to the present invention;

FIG. 9 shows an alternative hydraulic shock resist according to the present invention;

FIG. 10 shows another assembly of a hydraulic shock resist according to the present invention;

FIG. 11 is a front view of an isolating-adsorbing-type covering-uncovering member which is most suitable for combined heat and power generation according to the present invention;

FIG. 12 is a top view of FIG. 11;

FIG. 13 is a top view of an alternative rolling-type covering-uncovering member according to the present invention;

FIG. 14 is a top view of an alternative rotary-vane-type covering-uncovering member according to the present invention;

FIG. 15 is a top view of an alternative push-pull-type covering-uncovering member according to the present invention;

FIG. 16 is a top view of FIG. 15;

FIG. 17 shows the fourth embodiment according to the present invention, i.e., a hinged light collecting mirror and all the associated elements are replaced with a fixed connection light collecting mirror, and

FIG. 18 shows the fifth embodiment according to the present invention, i.e., a superconducting cooler and a hinged light collecting mirror and the like are replaced with a liquid radiating and a fixed connection light collecting mirror.

### DETAILED DESCRIPTION OF THE EMBODIMENTS

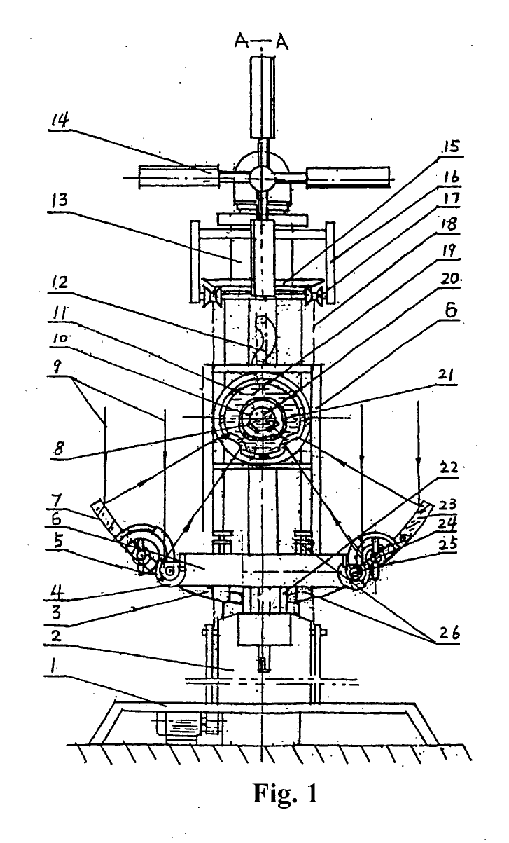

In FIG. 1, 1 is a base; 2 is an automatic sun-tracking machine; all the different automatic sun-tracking machines can be used in the hinged connection light collecting mirror system only if their precision meet the requirement; 3 is a main light collecting mirror; 4 is a slide chamber of a cavity-type shock resist; 5 is a piston; in this embodiment, both the piston and the slide chamber are circular; if the piston and slide chamber are made linear, a mechanism for transferring linear movement to circular movement should be added; 6 is a collecting carrier which is fixedly connected to the object carrier 22 which in turn is movably connected to the automatic sun-tracking machine; 7 is a west auxiliary light collecting mirror; 8 is a light collecting photovoltaic cell, hereinafter shorted as a light collecting cell; 9 denotes sunlight; 10 is a light collecting cell seat within which a evaporative section of a heating tube is located; 11 is an outer transparent cover tube of an uniform light device; it is linear focusing in this embodiment; 12 is a flexible connection tube that is a heat isolation section of the heating tube; it can be one tube or several tubes.

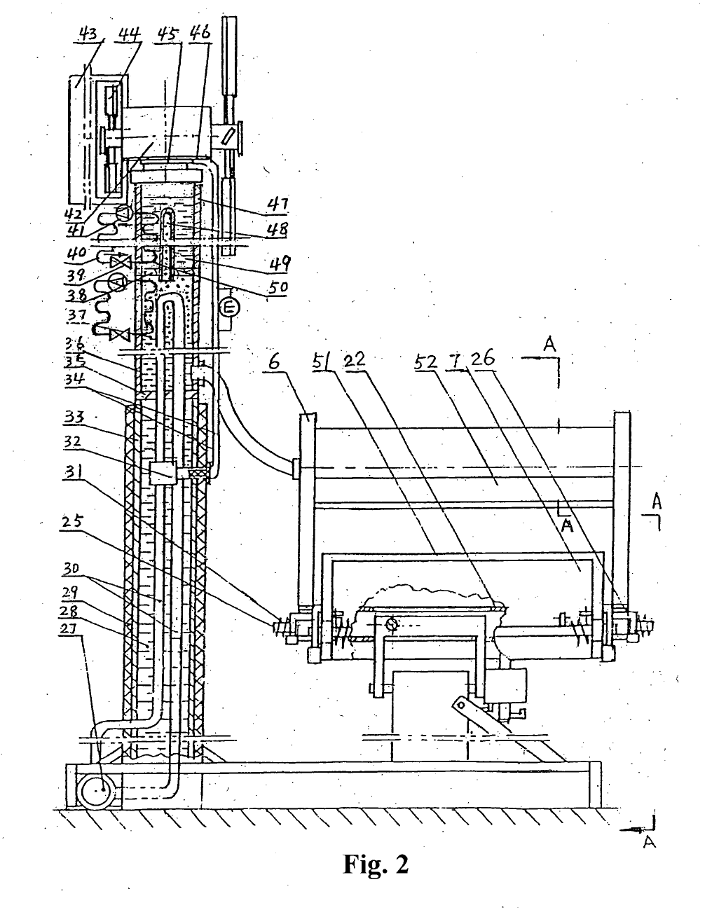

13 is a framework of wind power generator or a hollow column, which comprises three chambers: (1) an upper cooling and heating chamber, (2) a lower cooling and heating chamber, and (3) a condensation chamber of the heating tube; frameworks of small wind power generators, hereinafter shorted as wind power generator, are mostly a long hollow cylinder; it would be wasteful if the space within the hollow column is not utilized; in the present invention, this space is divided into three chambers to be filled with operation medium therein, so that the gravity center of the wind power generator can be descended much lower than that without operation medium so as to increase the stability thereof and to resist strong wind, its base of the framework is coupled to a base of the sun-tracking machine 1 to produce a interdependent effect; furthermore, since the wind and solar light have a disadvantage of discontinuousness; the combined wind and solar power generation can greatly decrease the discontinuousness of generation to allow an accumulator, a controller and an inverter etc. to be used for both wind and solar power generators, thereby to decease the cost of the power generation and elongate the durability of the accumulator; so the above three chambers could also be constructed as a hollow column only used for the solar power generator; it is not as profitable as adding an additional wind power generator formed by a wind wheel 14 and an electromagnetic generator 42 etc. (FIG. 2) at the top of this hollow column. One wind wheel can be added, and if two reversed rotation wind wheels are added, wind power will be effectively utilized and the diameter of wind wheels can be reduced.

If a high platform which is as high as the partition plate 35 in the left side of collecting carrier 6 in FIG. 2 is provided, the sporting cylinder of the wind power generator or the base of the hollow column 13 will be under the lower partition plate 35; in this case, the lower cooling and heating chamber 33 is unnecessary, and only the heating tube condensation chamber and the upper cooling and heating chamber are retained.

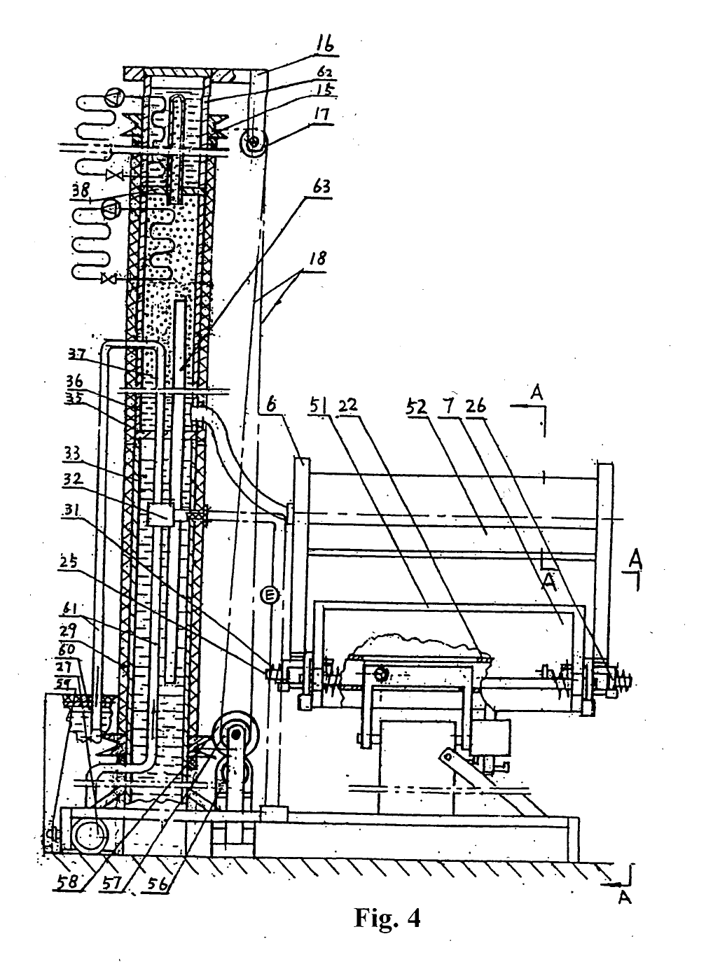

15 is a guider for a covering-uncovering member, flexibly elastic transmission elements 18 located in both sides of the guider wind the circumference of the guider in the reversed directions and then is fixedly connected on the circumference of the guider; the internal circle of the guider is carried by the framework 13 of the wind power generator or a hollow column 62 (see FIG. 4), and is movably connected to and rotate around the latter; 16 is an upper support frame of a spindle of a pulley 17; 19 is transparent refraction medium which forms the liquid lens; 20 is the operation medium of the heating tube; 21 is an inter linear light focusing transparent cover tube; it, along with an outer cover tube 11 and transparent refraction medium 19, can form a column lens which has a concave or convex cross section of any curved surface; a layer between the inter cover tube 21 and the light collecting photovoltaic cell seat 10 is a vacuum or negative pressure layer to isolate heat in order to make the operating temperature of the light collecting cells below the environment temperature to improve the efficiency of power generation; 22 is an object carrier; 23 is an east auxiliary light collecting mirror; 24 is a hinge shaft of the auxiliary light collecting mirror; 25 is a hinge shaft of the main mirror; 26 is a stop for the hinged light collecting mirror; it interacts on the spring 31 shown in FIG. 2 to keep the hinged light collecting mirror at a correct working position when there is no wind.

FIG. 2 shows a transmitting section in which a transmission of a covering-uncovering member has been removed; in this FIG. 2, 27 is a cycling pump; 28 is medium of the cooling and heating chamber; 29 is a heat isolation layer; 30 is an adsorbing and transmitting device in a form of hydraulic cycling tube; 31 is a restoring spring; 32 is a heat absorbing end of a Peltier cooling circuit; 33 is a wall of the lower cooling and heating chamber; 34 is the Peltier cooling circuit; 35 is a lower partition plate; 36 is a wall of the condensation section of the heating tube; 37 is operation medium of the heating tube; 38 is an upper partition plate; since the framework of the wind power generator is very high and the volume of its cavity is very large, the whole cavity can be partitioned into three chambers; 39 is a expansion valve associated with the heat pump; 40 is a heat producing end of the heat pump, which can access the heat consumption place of users; 41 is a compressor for the heat pump; 42 is an electromagnetic power generator; 43 is an orientation tail wing for the wind power generator; 44 is an auxiliary wind wheel; 45 and 46 both are the electrical connection poles by which the Peltier cooling circuit accesses the heat radiator of the wind wheel; the heat producing end of the Peltier cooling circuit can be electrically connected to any other place where heat is easily radiated, for example, the base of the automatic sun-tracking machine etc.; the power source E of the Peltier cooling circuit had better use the residual current of the wind power or solar power generation, for example, the current which is rejected to be charge the accumulator by the controller since the accumulator is full to prevent it from overcharged, and the current that cannot charge the accumulator or that cannot be output to the power grid since the voltage generated from the weak wind or sunlight is too low etc.; of course, the cheap commercial electrical power during valley load hours can also be used.

47 is a wall of the upper cooling and heating chamber; 48 is a heat exchanger which extends into the upper cooling and heating chamber and communicates with the condensation chamber of the heating tube, and thereby can construct as a gravity heating tube; 49 is medium for cooling or absorbing in the upper cooling and heating chamber; 50 is a evaporative cooling end of the associated heat pump; 51 is a framework of the light collecting mirror; 52 is a uniform light generator with a liquid lens formed by a linear-focusing light cover tubes.

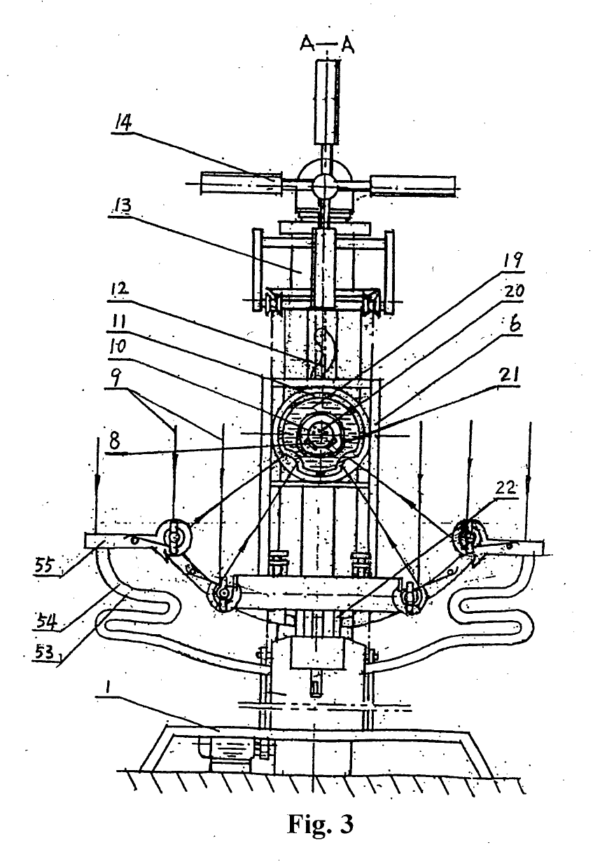

FIG. 3 shows the present invention with an adsorptive cooling device to utilize the free day-night temperature difference and to exert the sun-tracking machine's capability in order to increase the cooling amount of the lower cooling and heating chamber to supply the condensation chamber; to transmit the cooling energy from the lower cooling and heating chamber into the condensation chamber, a close hydraulic cycling tube system in FIG. 2 can be used, but an open hydraulic cycling tube system 61 of FIG. 4 can also be used, or the conductive component 63 made of heat conductive material shown in FIG. 4 can also be used; the non-gravity heating tube with capillaries can also be used, but the heat exchange effect thereof is not as good as that of the hydraulic cycling tubes; in FIG. 4, 56 is a driving assembly for a rotary-vane-type or isolating-adsorbing-type covering-uncovering member; 57 is a roller; 58 is a transmission; 62 is a hollow column which includes the condensation chamber of the heating tube and the upper and lower cooling and heating chambers; 62 will become a wind power generator if a wind wheel and an electromagnetic power generator are installed at its top; 59 is a valve for the open cycling tube system; 60 is an outer cooling source.

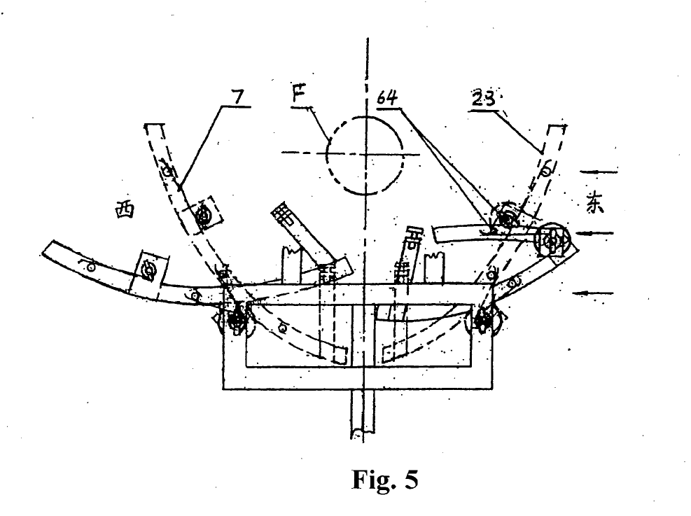

The solid line in FIG. 5 denotes the light collecting mirror in the wind sheltering state under noxious strong east wind; the dashed line in FIG. 5 denotes the light collecting mirror in the reset normal state after the strong east wind has passed; 64 is a spring limiter.

As shown in figures, the strong eastern wind makes the east auxiliary mirror 23 turn west, this can minimize wind resistance and can also avoid the damage of the power generation tubes due to the collision with the power generation tubes F, and the west auxiliary mirror 7 and the like also turns to the minimal wind resistance state. The sheltering state will be opposite to one of FIG. 5 in case of strong western wind, and the case of southern wind or northern wind can also be deduced by this analogy.

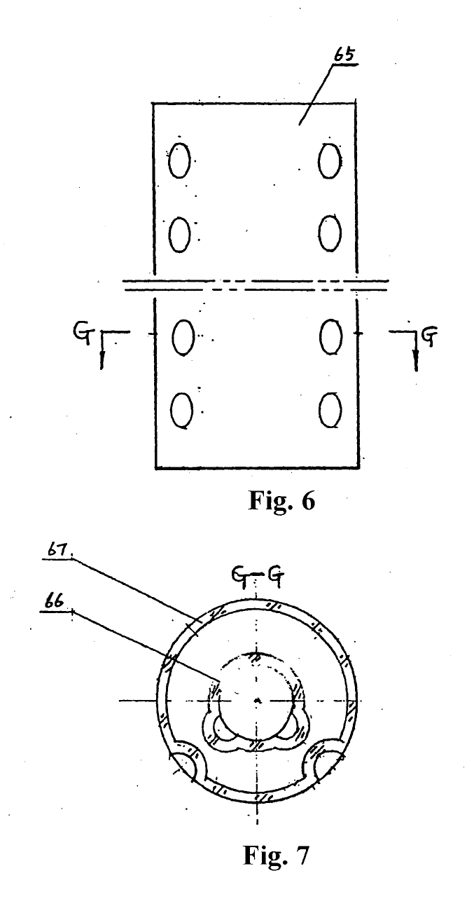

FIG. 6 shows a point light collecting cover tube 65 which is another embodiment of a liquid lens.

In FIG. 7, 66 is an inner transparent tube shell for the point light collecting cover tube; 67 is an outer transparent tube shell of the point light collecting cover tube; if the layer between them is filled with transparent medium, a concave or a convex lens can be formed; the lens can be a spherical surface lens or a non-spherical surface lens according to the needs.

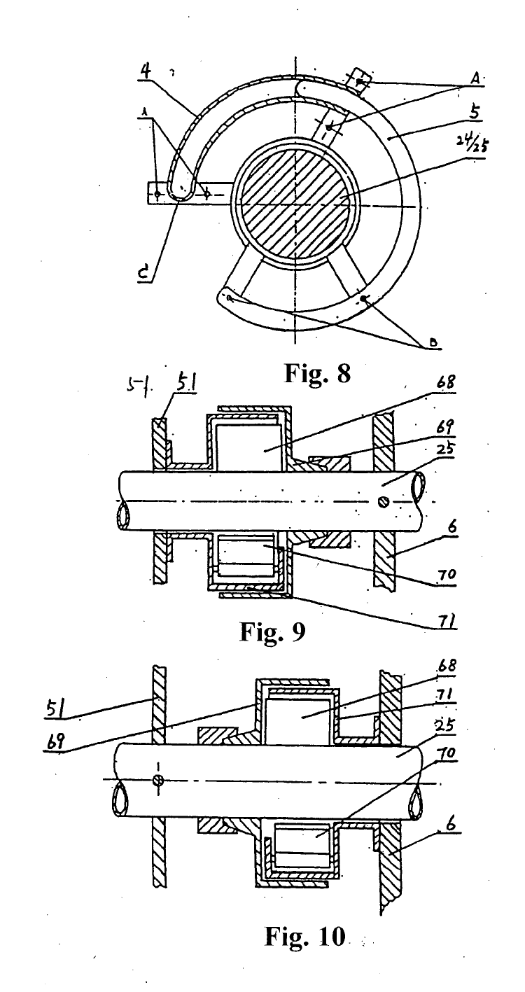

FIG. 8 is a cross section view of a cavity-type shock resist; there are four small holes A and two small holes B therein for connecting the shock resist with the elements A and B which are hinged with each other; C is the ventilated orifice which can be replaced with a clearance between the piston 5 and the slide cavity 4.

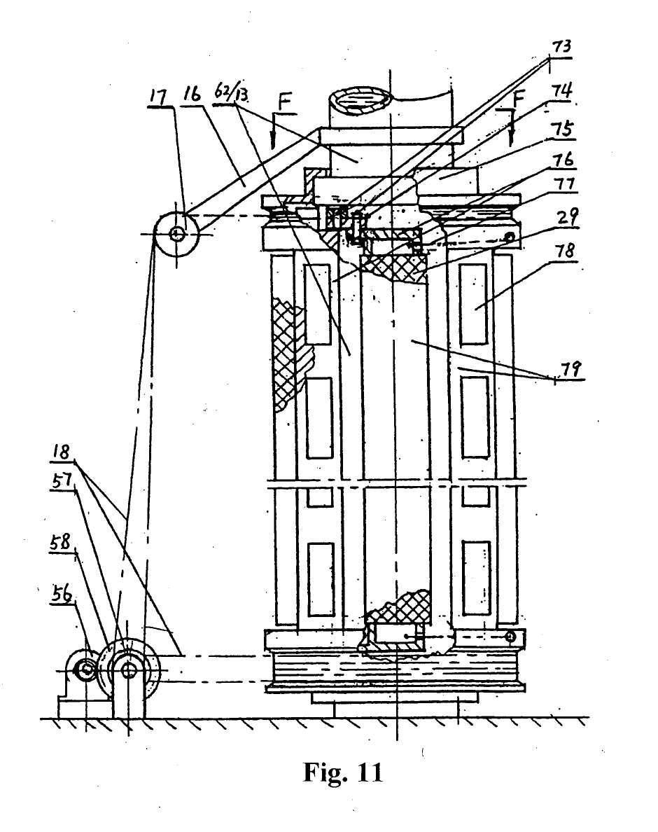

FIG. 9 is a cross section view of a hydraulic shock resist. 68 is a partition plate fixedly connected to the hinge shaft 25; 69 is a cavity shell which forms rest seal with the hinge shaft 25; 70 is a valve; 71 is a valve shell which is fixedly connected to the framework of the hinged mirror 15; the valve shell 71 forms movable seal with the hinge shaft 25 and rest cavity shell 69, the valve shell 71 is movably connected to the valve 70 and carries the valve 70; hydraulic medium fills the cavity formed by the valve shell 71, the cavity shell 69, and the hinge shaft 25 (medium is not shown in FIG. 9 in order to show the system clearly); FIG. 10 is another assembling arrangement of FIG. 9; all the elements, except the framework of the mirror 51 and the collecting carrier 6, exchange their positions of the moving members and rest members.

In FIG. 10, the hinge shaft 25 is fixedly connected to the mirror framework 51; a rest seal presents between the cavity shell 69 and hinge shaft 25, so the cavity shell 69 will rotate along with the hinged mirror framework 51 and the shaft 25; the partition plate is still fixedly connected to the shaft 25; the valve shell 71 movably connected to and carrying valve 70 is fixedly connected to the collecting carrier 6; the cavity, formed by valve shell 71, cavity shell 69, and hinge shaft 25, is filled with liquid medium. Due to the mounting manners of the valves at both sides or the dissymmetry of their shapes, in any one of the two assembling arrangements in the FIG. 9 or 10, when the east, south, west, north damaging storm comes and the hinged mirror framework 51 is forced to rotate so as to shelter wind, the valve 70 will open and allow liquid medium to flow backward, and the hinged mirror framework can rotate as it is not obstructed by the liquid medium; after the storm has passed, the hinged mirror framework 51 restores to the operation positions under the force from the restoring spring 31, i.e., when the framework rotates reversely, the valve 70 closes automatically, thus make the hinged mirror framework and the light collecting mirror meet a large resistance, so they can only be reset gradually as the medium slowly flows backward through the gap to prevent the light collecting mirror from shaking and being damaged so as to assure the safety thereof.

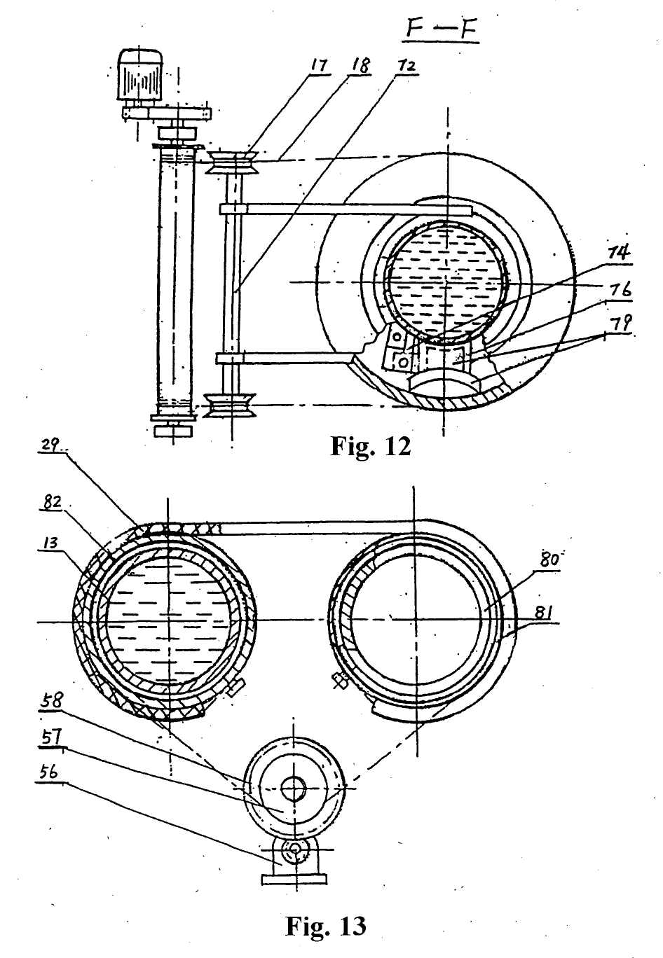

FIG. 11 is a front view of an isolating-adsorbing-type covering-uncovering member which is mounted on the circumference of the hollow column 62 or the framework 13 of the wind power generator; FIG. 12 is a top cross section view taken in line F-F of FIG. 11; in FIG. 11, 73 is a pin or a pin shaft; 74 is a horizontal-vertical plate which is hinged on the circumference of the framework of the wind power generator 13 or the hollow column 62; 75 is a overturning ring which internal ring is carried by and can rotate around the framework 13 or the hollow column 62; 76 is an isolating-adsorbing support plate of a isolating-adsorbing plate 79; both the upper and lower ends of the support plate 76 are hinged to the horizontal-vertical plate 74, or to the wall of the framework 13, or the wall of hollow column 62; it is made of a high heat conductive material; its back surface can engage with the wall of the framework 13 or the hollow column 62, and there are ventilated windows 78 in both sides of the support plate and an opening in the front surface so as to form the isolating-adsorbing plate 79 by integrating with the heat isolation layer 29; there is a flexibly elastic element 77 or a flexible transmission element 18 as a torque transmitting connection between the isolating-adsorbing plate 79 and the overturning ring 75; the overturning ring consists of an internal ring and an external ring connected each other; the internal ring of the overturning ring 75 is movably connected to the framework 13 or the hollow column 62; the external ring of the overturning ring 75 is wound by the flexibly elastic transmission element 18 one end of which is fixedly connected on the circumference of the external ring, and another end thereof rounds through the pulley 17 and winds around the roller or rolling drum 57, then is fixedly connected on the circumference thereof; roller 57 is connected, to the driving assembly 56 to transmit a torque, by the transmission 58 which is controlled by a sensor or a signal controller; the sensor or controller belongs to the prior art and won't be described here; pulley 17 is set in its shaft 72 which is fixedly connected to the framework of the wind power generator 13 or the hollow column 62 via its support frame 16.

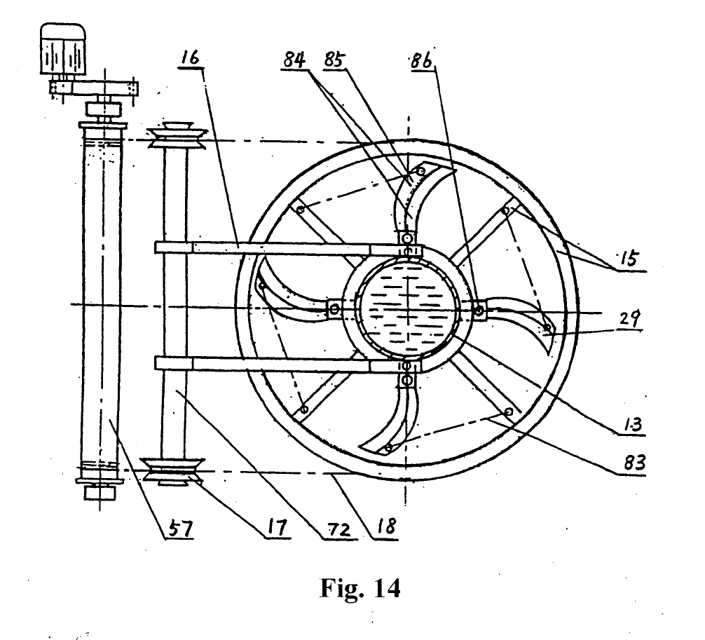

FIG. 13 is a top view of a rolling covering-uncovering member. In FIG. 13; 80 is an auxiliary support column 80 which is parallel to the framework of the wind power generator 13, 81 is an auxiliary roller nested and rotating around the auxiliary support column 80; 82 is a main roller which nests and can rotate around the wind power generator 13; one end of the heat isolation layer 29 is fixedly connected on the circumference of the main roller 82; the other end thereof is fixedly connected on the circumference of the auxiliary roller 81; the roller or rolling drum 57 is respectively connected to the main roller 82 and the auxiliary roller 81 so as to transmit a torque; the rolling drum 57 is connected to the driving assembly 56 to transmit a torque via a transmission 58; the driving assembly 56 is controlled by the signal controller or sensor; both the main roller and the auxiliary roller can be formed in a form of grille or grid; the heat isolation layer 29 can wind around the main roller 82 so as to cover framework 13 to isolate heat, and can wind around the auxiliary roller 81 so as to uncover framework 13 to radiate heat.

Another embodiment of the covering-uncovering member is to remove the main roller 82 and connect one end of the heat isolation layer 29 with a section of a flexibly elastic transmission element; the other end of the flexibly elastic flexibly elastic transmission element winds around and then is fixed to the wind power generator framework 13 or hollow support column 62; the other end of the heat isolation layer is still fixed to the auxiliary roller 81; when it is necessary to uncover the wind power generator framework 13 or the hollow support column to radiate heat, the driving assembly drives the auxiliary roller 81 to rotate and makes the heat isolation layer wind around the circumference thereof; since the flexibly elastic transmission element can be stretched further than an whole turn around the wind power generator framework 13 or hollow support column 62, when it is necessary to cover the wind power generator framework 13 or hollow support column 62 to isolate heat, the driving assembly will release the auxiliary roller 81, and the heat isolation layer will return and wind around the wind power generator framework 13 or hollow support column 62 by the restoring force of the flexibly elastic element.

FIG. 14 is a top view of a rotary-vane-type covering-uncovering member which the front view is included in FIGS. 1 or 3, and its left view is shown in FIG. 4; in FIG. 14, the guider 15 consists of an internal ring, an external ring and a link spoke; the internal ring of the guider 15 is carried by and movably connected to the wind power generator framework 13, and can rotate around the latter; the flexibly elastic transmission element 18 winds several turns on the external ring of the guider 15; one end of the flexibly elastic transmission element 18 is fixedly connected on the circumference of the external ring of the guider 15, and the other end of the flexibly elastic transmission element 18 winds through the pulley 17 and reaches the roller or rolling drum 57, then winds around the roller or rolling drum 57 several turns and is fixedly connected on the circumference thereof; the roller 57 is connected to the driving assembly 56 via a transmission to transmit a torque; in the figures, 84 is a heat isolation vane which is hinged in the wind power generator framework 13 or hollow support column 62 via a hinge shaft 86; the heat isolation vane 84 consists of a vane support plate 85 and a heat isolation layer 29 and is connected to the guider 15 by a flexibly elastic transmission element 83; for example, in FIG. 14, if the guider 15 turns a certain angle in the clockwise direction, it will pull all heat vanes to a lying down state so as to cover the framework 13 to isolate heat; FIG. 14 shows a “uncovering” state; in this case, the three chambers contained in the framework 13 can radiate heat to or absorb heat from the environment.

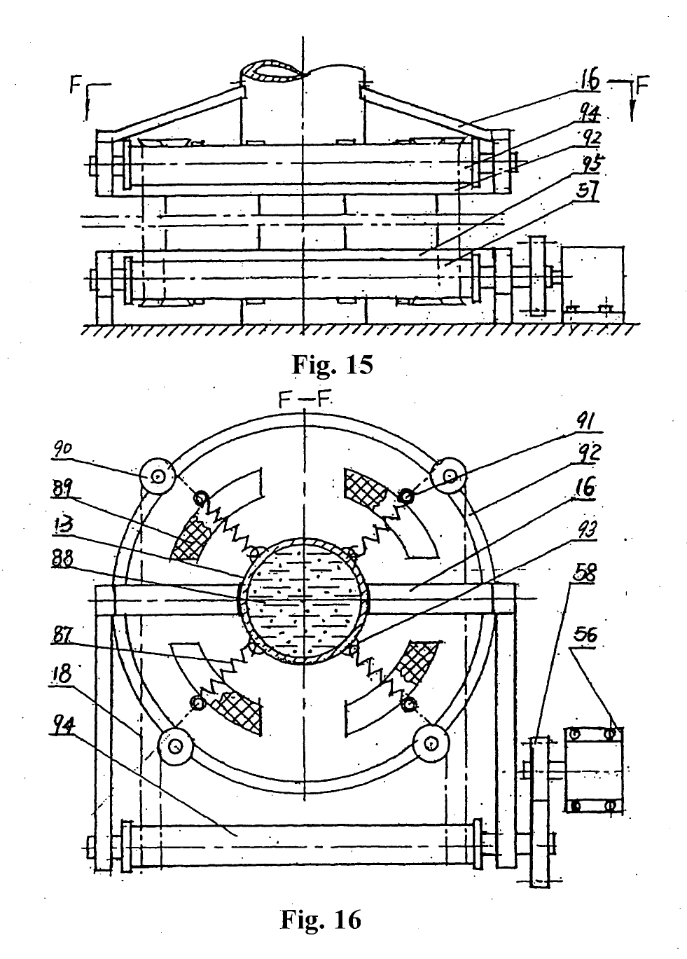

FIGS. 15 and 16 are front and top views of a push-pull type covering-uncovering member; 89 is a heat isolation petal; 90 is a horizontal pulley; 91 is a heat isolation petal pile for fixing the upper end of the flexibly elastic transmission elements 18; 92 is an outer mounting which is fixedly connected to the support column or wind power generator framework 13 via the upper support frame 16; 93 is an inner mounting which is fixedly connected to the support column 13; herein it is a ring to which one end of the spring 87 is connected; the other end of the spring 87 is connected to the heat isolation petal pile 91; 94 is a rotating member; the flexibly elastic transmission element 18 passes through the pulley 90 and the rotating member 94, then runs down to the roller or rolling drum 57 in FIG. 15, and winds around and then is fixedly connected on the circumference of the roller or rolling drum 57; the rolling drum 57 is connected to the driving assembly 56 via a transmission to transmit a torque; the distance between the centers of the rotary member 94 and the upper outer mounting 92 and the distance between the centers of the roller 57 and the lower outer mounting 95 do not change with time; the transmission 58 may be connected to a worm gear in series (not shown in the drawings), when the electric motor 56 pulls the heat isolation petal 89 away to radiate the heat in the reserve radiation chamber and cooling and heating chamber within the support column 13, in the state shown as FIG. 16, this state will be kept unchangeable; when the electric motor 56 rotates reversely, the spring 87 (it is an extension spring in the drawing) forces the heat isolation petal 89 to cover the hollow support column 13 so as to isolate heat.

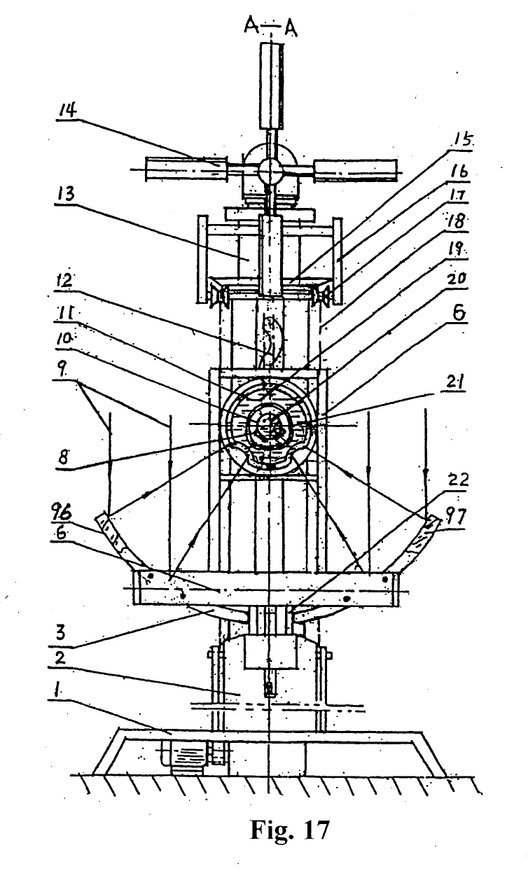

In FIG. 17, except for that the fixed connection light collecting mirror is replaced with the hinged light collecting mirror and other members related to the hinge connection, the other associated members are unchanged. After such replacing, the light collecting mirror losses the functions of automatically sheltering wind and resisting shock. it is necessary to rely on the relevant function of the automatic sun-tracking machine in order to avoid the light collecting mirror and the whole system being damaged by wind, for example, such automatic sun-tracking machine generally is driven by two electric motors (double axes tracking), the controller should have an automatic wind protecting circuit and a wind sensor etc.; if case of a storm, the automatic sun-tracking machine will be turned to the middle position as shown in FIG. 17 to reduce the wind resistance of the light collecting mirror (but it is not as small as the wind resistance of the hinged collecting mirror which can deformed automatically), and it will increase the cost of the automatic sun-tracking machine or the whole device, the automatic sun-tracking machine which has this function has been solved by the prior art, it won't be described here.

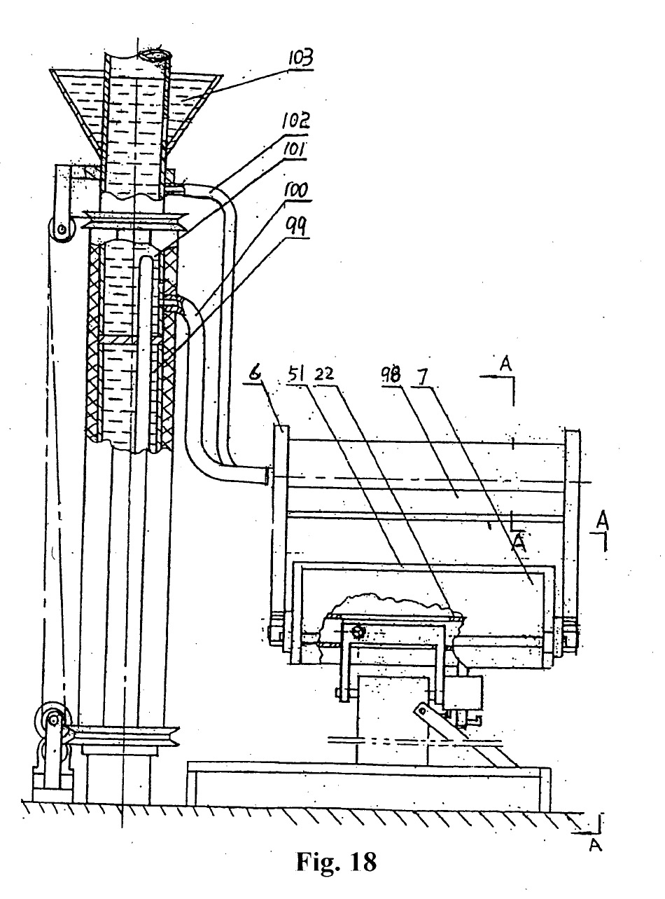

FIG. 18 is an embodiment in which the liquid heat radiator is replaced with the heat tube cooling system described above (other members, for example, the covering-uncovering member is unchanged except the heat tube cooling system). 98 is a uniform light generator; there is no evaporative section of heating tube within the cavity of the light collecting cell seat but a liquid cycling tube system which connects, by two flexible tubes 100 and 102, to the upper and lower openings of the reserve radiated chamber 101 which means a chamber that can reserve liquid and radiate heat; it is an upper chamber of the framework of the wind power generator 13 or the hollow support column 62 which lower chamber is the lower cooling and heating chamber 99; 103 is an evaporative cooling chamber which is connected to the reserve radiated chamber 101; this cooling way is relatively simple, but is not as good as the cooling system which uses the heating tube described above, because if the heat absorbing liquid does not incur phase change, the temperature thereof will increase.

In order to greatly increase the photovoltaic transduction efficiency of the photovoltaic cells and decrease the cost, the present invention uses an ingenious and very cheap way to improve the solar intensity at hundreds times and decrease the operating temperature greatly, since the intensity of the light current of the solar cell is proportional to the illumination intensity, and the open-circuit voltage increases as the solar illumination intensity increases, and as well output current decreases sharply as the operating temperature increases; so, cooling is very important for dropping the temperature; the present invention suggests using the residual current from the solar light and wind power generation to cool the system; the applicant further provides a cover-uncover technology which uses the day-night temperature difference to cool and reserve cold lest the residual current is not enough; this is very useful in northern area in which the day-night temperature difference is very high, even in summer, and this temperature difference may reach several dozen degrees, no need to mention the cooling in the winter, spring and autumn. In southern area, the day-night temperature difference is relatively small, but since the framework of the wind power generator is very high, it can reserve a great amount of the cooling medium; if the upper cooling and heating chamber is not enough, the lower cooling and heating chamber can be used; moreover, if the lower cooling and heating chamber is still not enough, an outer cold source can be added; it is best to use the integrated cooling system which combines the day-night cooling system, the adsorptive cooling system, the Peltier cooling system, the absorbing cooling system, and the metal hydride cooling system etc.; if the system cooperates with a heat consumption system, using a heat pump to cool the system, the temperature will be very low and the efficiency will be the best; the heat of sunlight is radiated to the photovoltaic cells; the relevant heat will be absorbed by the heating tube and be transmitted to the condensation chamber and the upper cooling and heating chamber, and then output to the heat consumption device after it is absorbed and enlarged; this can increase the photovoltaic transduction efficiency of the photovoltaic cells and greatly increase the heat used by the heat consuming device; so, the combined heat and power generation can greatly improve the efficiency of the utilization of solar power; when there is not solar light, the covering-uncovering member particularly the isolating-adsorbing-type covering-uncovering member in the present invention becomes the heat absorbing fin which absorbs a large amount of heat from air, and transmits the heat to the condensation chamber and cooling and heating chamber, which is collected in water for the usage of the heat pump; this will be much better compared to air source heat pump; since the air contact area of the evaporator of the air source heat pump is limited, the air contact area of the isolating-adsorbing plate and the cooling and heating chamber, on the contrary, is very large; it can absorb much more heat; the heat pump has a lot of kinds, and every kind of the heat pump can cooperate with the present invention, for example, the adsorptive heat pump, absorbing heat pump and metal hydride heat pump etc.; all can be cooperate with the system of the present invention.

It is too slow to transmit the cooling power of the lower cooling and heating chamber to the condensation chamber by using the heat conductive material; a hydraulic cycling pipe system can be used to accelerate heat exchange; the consumed electricity power by the pump is very little, because the system only needs to overcome the friction force of the water in tube, and does not need any power for lifting the water level; all these approaches can obtain a very good effect and cost little, and thereby reduce the cost sufficiently.

The present invention can greatly decrease the operating temperature of photovoltaic cells (the temperature is often kept below the environment temperature) by using the free power, and makes uniform light device highly efficient and cheap, so the photoelectric conversion efficiency is high, and the output power of each generator is large, thereby it is called high efficiency power generator.

The advantages of the present invention are as follows:

(1) the cooling method for the photovoltaic cells is advanced, it can greatly improve the generation efficiency of the photovoltaic cell and elongate the durability of the cell. The present invention is designed to radiate heat by the heat tube which is isothermal, the liquid absorbs heat and become a gas within the cavity of the light collecting cell seat, so the temperature of the cell hardly increases to allow it to generates power in the temperature much lower than the environment temperature;

(2) the cooling method is ingenious, it has a high efficiency and cost little, and can benefit from the waste: the system can utilize the day-night temperature difference and the affluent carrying capability of the sun-tracking machine to adsorb heat and cool, and utilize the residual current from the solar or wind power generation which can not be charged into the accumulator or be output to the network to cool; all these power are free, what to do just is let the covering-uncovering member to move several dozens seconds;

(3) the uniform light technology is advanced and cheap: in order to irradiate the photovoltaic cells in even intensity to increase the charging coefficient and the photoelectric conversion efficiency, the light collecting should be homogenized, so the corresponding lens are needed for this purpose. Since the solid lens is manufactured by grinding glass and it is too expensive, and the liquid lens is adaptable to be produced in large batch and is cheap. When single transparent cover tube is used, the photovoltaic cells are dip in the liquid, this may cause a lot of problems, for example, it is difficult to drop the temperature to low level, the uniform light effect is relatively low, and it is easy to leak current etc., so the double transparent cover tubes must be used instead of single transparent cover tube;

(4) it is safe and reliable and can prevent the system from being damaged by the strong wind: due to the hinge connected light collecting mirror etc. in the present invention, it can automatically shelter the strong wind, and an ingenious shock resist is used in the present invention, it will protect the glass members in the present invention.

As the wind and solar power generator works in the badly open condition, the applicant has developed an automatic system to shelter strong wind rather than to increase the support member's size and strength of the sun-tracking machine used in other light collecting power generation system, which may increase the deadweight and the material's cost;

(5) the upper cooling and heating chamber concept is firstly provided in the present invention; it realizes the gravity heat tube, and thereby saves the operation cost.

(6) it can use the combined heat and power generation, and the efficiency thereof is doubled so as to realize heating by using the solar power when there is sunlight: the electricity power generated from solar light and wind can be charged into the accumulator except for part of them consumed by the heat pump; when there is no sunlight in snowy days or at nights, the electricity power in the accumulator can supply the heat pump to heat, and the isolating-adsorbing-type covering-uncovering member will be in heat absorbing state (i.e. the state of FIG. 11) to absorb heat from the air to heat the water to supply the heat pump; its enthalpy is high;

(7) the integrated wind and solar power generation shares the accumulator, the converter, and the controller so as to at least reduce a half of the cost of these devices, and elongate the durability of the accumulator and supply electricity continuously;

(8) the integrated wind solar power generation system can change the framework of the wind power generator into a portion of the heating tube and the cold storing and refrigerating chamber, and is fixedly connected the framework of the wind power generator to the base support of the solar power generator, so that the barycenter of the wind power generator can be lowered, and its stability thereof is increased to decrease the mounting depth of the framework of the wind power generator, and the relevant cost as well, thus improve its ability for wind sheltering;

(9) the light collecting power generation system can largely increase the photoelectric conversion efficiency and decrease the consumed amount of photovoltaic cells and the cost of power generation.

Although the present invention is described according to some specific devices, it may be amended within the scope of the present invention; the scope of the present invention is limited by the attached claims.

What is claimed is:

1. A highly efficient light collecting and superconductive generator, hereinafter shorted as a highly efficient light collecting generator, comprising a light collecting photovoltaic power generation system, a cooling and radiating system, an automatic sun-tracking machine, and further comprising a wind power generator, in which the light collecting photovoltaic power generation system, hereinafter shorted as a light collecting generation system, comprises a group of light collecting mirrors with a wind-sheltering mechanism for meeting an emergency, an uniform light generator, an object carrier, and a collecting carrier, wherein:
A. the object carrier is movably connected to the automatic sun-tracking machine, the collecting carrier is fixedly connected to the object carrier, the group of light collecting mirrors with an wind-sheltering mechanism is connected to the collecting carrier or object carrier in the following two ways: one is a movable connection, i.e. hinging connection; the other is a fixed connection; the uniform light generator, which is located in or near to the public focus line/area/point of the light collecting mirror during operation, is supported by and connected to the collecting carrier; all the lighting planes vertical to the main axis of the respective light collecting mirror are vertical or constantly approximately vertical to sunlight;
B. the group of light collecting mirror hinged with a wind-sheltering mechanism consists of a light collecting mirror unit which is single light collecting mirror or double light collecting mirrors; the single light collecting mirror unit, hereinafter shorted as a single mirror unit, comprises a light collecting mirror installed in a mirror framework and a restoring spring, a stop and a hinge shaft, and further comprises a wind-sheltering plate and a shock resist; in which the mirror framework is hinged to the collecting carrier via the hinge shaft; the restoring spring, at the two ends, is connected to the collecting carrier and the light collecting mirror, respectively, so that the stop constantly keeping the hinged light collecting mirror in a correct operating position is located between the mirror framework and the collecting carrier;
the wind-sheltering plate is a plate-like member or a flat box member which can rotate the light collecting mirror to shelter the wind so as to suffer minimal wind resistance in case of a harmful strong wind;
C. a hinged double light collecting mirror unit, hereinafter shorted as a double mirror unit, consists of a main light collecting mirror and an auxiliary light collecting mirror, in which the main mirror is the said single light collecting mirror connected to the collecting carrier, and the auxiliary light collecting mirror is carried by the main light collecting mirror and comprises a light collecting mirror installed in an auxiliary mirror framework, a restoring spring, and a hinge shaft; the auxiliary light collecting mirror further comprises a shock resist; the auxiliary mirror framework is connected to the main mirror framework by the hinge shaft; the restoring spring, at both ends, is connected to the main mirror and the auxiliary mirror framework, respectively;
D. the uniform light power generator comprises a light collecting cell seat, a light collecting photovoltaic cells, and a connection circuit, and further comprises a uniform light element and a transparent cover tube; the light collecting cell seat has a chamber; the light collecting photovoltaic cell, hereinafter shorted as a light collecting cell, is carried by a wall of the of the light collecting cell; and the respective light collecting cell sheets are connected by the connection circuit to form a photovoltaic generating body which is surrounded by the transparent cover tube; the photovoltaic generating body forms a vacuum layer or a negative pressure layer between the photovoltaic generating body and the transparent cover tube; the uniform light power generator without the uniform light element is a photovoltaic power generating body, or called photovoltaic power generation tube;
E. the light collecting mirror with the wind-sheltering mechanism is a reflection light collecting mirror or a Fresnel lens; the sunlight directly irradiates on the light collecting cells through the light collecting mirror, or the sunlight passes through the uniform light element and then irradiates on the light collecting cells;
F. the cooling and radiating system comprises a fluid radiator which communicates with the chamber of the light collecting cell seat via a flexibly bendable connecting pipe through its port; the position of the port is higher than the highest position to which the light collecting cell seat can reach; the fluid radiator is a liquid radiator, or a condensation section of a heating tube formed by itself and the chamber of the light collecting cell seat and the flexible connecting tube; in this case, the chamber of the light collecting cell seat is a evaporative section of the heating tube; the flexible tube is a heat isolation section of the heating tube, with operation medium cycling therein; the light collecting cell seat and the flexible connection tube are filled with liquid in the case that the fluid radiator is a liquid radiator, and
G. the cooling and radiating system further comprises a cooler for cold source; the cooler for cold source is either an upper cold source which is located higher than the position of the cold source of the condensation section of the heating tube, or a lower cold source which is located lower than the position of the cold source of the condensation section of the heating tube; the cold source is a refrigerator which reserve cold energy; the refrigerator is a day-night temperature difference refrigerator, an ordinary heat pump refrigerator, an adsorption refrigerator, a Peltier refrigerator, a magnetic refrigerator, a metal hydride refrigerator, an absorbing refrigerator, or an integrated refrigerator.

2. The highly efficient light collecting and superconductive generator according to claim 1, wherein the day-night temperature difference refrigerator is either an upper day-night temperature difference refrigerator or a lower day-night temperature difference refrigerator; the upper day-night temperature difference refrigerator comprises an upper cooling and heating chamber, an operation medium and a covering-uncovering member; the covering-uncovering member is located around the upper cooling and heating chamber and is carried by the later one or by the hollow column which includes the cooling and heating chamber, or by a framework of the wind power generator; the lower day-night temperature difference cooler includes a lower cooling and heating chamber, operation medium therein and a covering-uncovering member, and further comprises an absorbing and transmitting device; the covering-uncovering member is located around the lower cooling and heating chamber taken as the carrier, or a hollow column containing the cooling and heating chamber as the carrier, or optionally with an associated framework of the wind power generator taken as the carrier; in the case that the heating tube is not a non-gravity heating tube, an absorbing and transmitting device is needed as a heat absorbing and transmitting device which lower section extends into the medium of the lower cooling and heating chamber, and which upper section extends into the medium of the condensation section of the heating tube; preferably the absorbing and transmitting device is a heat conductive element made of high heat conductive material, or a medium flowing pipe which is either an open loop or a close loop; a driven power source of medium flowing pipe or switch circuit of the driven power source is supplied by the solar cell which either is or is not synchronous with the strong or weak to the density of the sunlight, or by another outer power source;
the ordinary heat pump cooler comprises a heat pump, a upper cooling and heating chamber, operation medium therein and a covering-uncovering member; the evaporative cooling section of the heat pump is located within medium of the upper cooling and heating chamber; a compress heat producing section of the heat pump is located within the heat consumption device which is outside the cooling and heating chamber; the associated covering-uncovering member is located around the upper cooling and heating chamber taken as carrier; optionally the framework of the wind power generator containing the upper cooling and heating chamber or the hollow column is taken as carrier; a part of the condensation section of the heating tube extents into medium of the upper cooling and heating chamber to form a gravity heating tube, or extents into medium of the lower cooling and heating chamber to form non-gravity heating tube; the evaporative cooling section of the heat pump directly extends into medium of the condensation section of the heat pump, or extends into medium of the lower cooling and heating chamber;
an evaporator of the adsorption cooler is located within medium of the lower cooling and heating chamber, or is the lower cooling and heating chamber; an adsorption-desorbing chamber thereof is located under sunlight, or is flat box wind-sheltering member of the single-member light collecting mirror, one end at the heat radiator is connected to the adsorption-desorbing chamber, the other end is connected to the evaporator, the absorbing-transmitting device is located between the lower cooling and heating chamber and the condensation chamber of the heating tube to form connection for exchanging heat; the covering-uncovering member is installed around the lower cooling and heating chamber;
the Peltier cooling device comprises a heat absorbing end and a heat radiation end of a circuit made of two different kinds of materials connected according to Peltier effect, with the electric current following in the direction prescribed by the Peltier cooling effect, in which the heat absorbing end is inserted into the condensation chamber, the power generation tube or the upper cooling and heating chamber, and the heat radiating end is either inserted into the heat consumption device or into somewhere easy to radiate; the power source of the Peltier cooling device comes from residual current supplied by the light collecting power generator cell, or from residual current supplied by the wind power generator, or from other outer power source, and
the integrated cooling is to use two or more than two cooling approaches at the same time.

3. The highly efficient light collecting and superconductive generator according to claim 2, wherein the cooling and heating chamber and the condensation chamber of the heating tube is an internal chamber of a hollow column or an internal chamber of the framework of the wind power generator; the internal chamber is partitioned into three chambers consisting of an upper cooling and heating chamber, a lower cooling and heating chamber and a condensation chamber by partitions, or the internal chamber is partitioned into two chambers consisting of an upper cooling and heating chamber and a heating tube condensation chamber by a partition, all these cooling and heating chambers are called inner cooling and heating chamber, hereinafter shorted as cooling and heating chamber, and the other cooling and heating chambers except the above chambers are called outer cooling and heating chambers; a covering-uncovering member which is installed around the cooling and heating chamber and condensation chamber is an isolating-adsorbing-type covering-uncovering member, a rotary-vane-type covering-uncovering member, a rolling covering-uncovering member, or a push-pull covering-uncovering member;
the isolating-adsorbing-type covering-uncovering member comprises an isolating-adsorbing plate, a heat isolation sheet, an overturning ring, a flexibly elastic transmitting force element which is hereinafter shorted as a flexibly elastic element, and a driving assembly, or further comprises a horizontal-vertical plate, or more further comprises a signal generator and a sensor; the isolating-adsorbing plate is formed by the combination of an isolating-adsorbing support plate and a heat isolation layer; the isolating-adsorbing plate either prevents the heat transmission between the wall of the upper or lower cooling and heating chamber or the wall of the condensation chamber and the environment, or becomes a radiation sheet for the upper or lower cooling and heating chamber or condensation chamber, or becomes a plate product of heat absorbing sheet for absorbing heat from the environment to improve the efficiency of the heat pump when the temperature of an evaporative cooling end of the heat pump is very low; an opening for supporting, extending and carrying the heat absorbing sheet is provided at the front surface of the isolating-adsorbing support plate, and ventilated windows are provided at both sides of the isolating-adsorbing support plate; the back surface of the isolating-adsorbing plate is made in such a shape that allows it to engage with the wall of the cooling and heating chamber or the wall of the condensation chamber; on one hand, the isolating-adsorbing plate engages and disengages with the wall of the cooling and heating chamber or the wall of the condensation chamber by the indirectly movable connection, preferably hinged connection, between the horizontal-vertical plate and the wall of the cooling and heating chamber or the wall of the condensation chamber, or by directly hinging on he wall of the cooling and heating chamber or the wall of the condensation chamber, and the horizontal-vertical plate is a transition plate hinged on the wall of the cooling and heating chamber or the wall of the condensation chamber; on the other hand, the isolating-adsorbing plate is connected to the overturning ring via the flexibly elastic element or flexible transmitting element; the overturning ring is carried by either the hollow column or the framework of the wind power generator and rotating around the latter, or is directly connected or indirectly via a force transmitting device connected to the driving assembly to transmit a torque; the driving assembly is controlled by the either signal controller or the sensor;
the rotary-vane-type covering-uncovering member comprises a heat isolation support plate, a heat isolation sheet, a flexibly elastic element, a force transmission element, a guider, and a driving assembly, and further comprises a signal controller and a sensor, and it can more further comprises a horizontal-vertical plate, in which the heat support plate after the heat isolation sheet is connected and spread is called heat isolation vane; on one hand, the heat isolation support plate is directly hinged on or indirectly hinged on via the horizontal-vertical plate hinged on the wall of the cooling and heating chamber or the wall of the of the condensation chamber; on the other hand, the heat isolation vane is connected to the guider by the flexibly elastic element; the said guider, via the inner circle, is movably connected to the hollow column or the framework of the wind power generator, and is carried by and rotates around the latter; the guider is directly connected or indirectly connected via the force transmission element to the driving assembly to transmit a torque; the driving assembly is controlled by either the signal controller or the sensor;
the rolling covering-uncovering member consists of two types:
the first type comprises a heat isolation layer, a primary roller, an auxiliary roller, an auxiliary column and a driving assembly, and further comprising a flexibly elastic element and a signal controller, in which the primary roller is movably connected to and thereby allow the primary roller to rotate around the wall of the cooling and heating chamber or the wall of the condensation chamber; the auxiliary column is parallel to the axis of the cooling and heating chamber or the axis of storing or radiating chamber, the auxiliary roller which rotates around the auxiliary column is nested on the circumference of the auxiliary column; one end of the heat isolation layer is fixed on the circumference of the primary roller after winding the primary roller; optionally one end of the heat isolation layer is connected to one end of the flexible elastic element, then the other end of the flexible elastic element is fixedly connected to the primary roller; the other end of the heat isolation layer winds around and then is fixedly connected on the circumference of the auxiliary roller; both the primary roller and the auxiliary roller are fixedly connected to force transmission pulleys to form connection with the driving assembly for transmitting a torque; the driving assembly is connected to and controlled by the signal controller;
the second type of the rolling covering-uncovering member comprises a heat isolation layer, an auxiliary shaft, an auxiliary roller, a flexibly elastic member, a driving assembly, and a signal controller; wherein one end of the heat isolation layer is connected to the flexibly elastic member which the other end winds around and then is fixedly connected to the wall of the cooling and heating chamber or the wall of the condensation chamber; the other end of heat isolation layer is either fixedly connected to the wall of the auxiliary roller, or is connected to the flexibly elastic member, winding around the auxiliary roller, and is then fixedly connected to the wall thereof; the auxiliary roller that rotates around the auxiliary column is movably nested on the wall of the auxiliary column and fixedly connected to a force transmission wheel which is constructed to connect with the said driving assembly to transmit a torque; the driving assembly is connected to the signal controller, and
the push-pull covering-uncovering member comprises a plurality of heat isolation petals, a pull assembly, a roller or rotating drum, and a driving assembly; it further comprises an action signal generator, in which the said pull assembly enables the heat isolation petals to move periodically under action of the driving assembly; the said pull assembly comprises an inner mounting, a spring, a flexible transmission element, an outer mounting, and a pulley, in which one end of the spring is connected to the heat isolation petal, and the other end thereof is connected to the inner mounting; one end of the said flexible transmission element is connected to the heat isolation petal, the other end thereof winds the pulley installed in the outer mounting and then is directly or indirectly connected to the roller or rotating drum, or, the pulls assembly is construed as another combination, in which one end of spring is connected to the outer mounting, and the other end thereof is connected to the heat isolation petal; one end of said flexible transmission element is connected to the heat isolation petal, and the other end thereof winds the pulley installed in the inner mounting, and then is directly or indirectly fixedly connected to the roller; the roller is constructed to connect with the driving assembly to transfer the torque; the driving assembly and the signal generator is either an integrated structure or a separated structure in communication with each other by the signal emitted by the signal generator; the inner mounting is the member nearest to the storing and radiating chamber, and the outer mounting is the member relatively further to storing and radiating chamber.

4. The highly efficient light collecting and superconductive generator according to claim 1, wherein the axis or the extended line of the axis of the hinge shaft of the single light collecting mirror, or of the hinge shaft of the main light collecting mirror of the double light collecting mirrors, divides the said light collecting mirrors into two unequal portions; the sheltering plate of the single light collecting mirror or the auxiliary light collecting mirror of the double light collecting mirrors is hinged in the side of the smaller portion so as to allow the sheltering plate or the auxiliary light collecting mirror to keep in a correct operation position so as to install the stop and the restoring spring near the respective hinge shaft; the sheltering plate or the auxiliary light collecting mirror is rotated in one direction to shelter the wind.

5. The highly efficient light collecting and superconductive generator according to claim 1, wherein the shock resist is a hydraulic shock resist, a chamber shock resist, or a elastic force shock resist; the hydraulic shock resist is installed between a hinging member and a hinged member, the hinge between both is a shaft fixedly connected to the hinging member, or is a spindle fixedly connected to the hinged member; the hydraulic shock resist comprises a chamber shell, a baffle, a valve and a valve shell, in which the baffle is fixedly connected to the shaft fixedly connected to the hinging member; the chamber shell passes through the shaft to connect with the shaft in rest seal manner and receives a part of the baffle and the valve shell, and the chamber shell is connected with the part in movable seal manner; the valve is movably connected to and is carried by the valve shell; the space between the valve and the baffle is increased or reduced, the valve shell is fixedly connected to the hinged member so as to form movable seal with the shaft; operation medium is filled among the chamber shell, the shaft and the valve shell;
optionally all the rest and moving members except the hinging members and hinged members are interchanged, i.e., the hinge shaft is fixedly connected to the hinged member and movably connected to the hinging member, in this case, the valve shell carrying the valve is fixedly connected to the hinging member as the baffle is fixedly connected to the spindle; the rest chamber shell which previously receives a part of the baffle and the valve shell becomes a movable shell and is fixedly connected to the spindle to form a rest seal, and a movable seal is still formed between the chamber shell and valve shell; operation medium is filled among the movable chamber shell, the spindle and the valve shell;
the chamber shock resist comprises a hollow cylinder and a piston cooperating with the cylinder; there are either small holes in the hollow cylinder or piston, or there is a clearance between contacting surfaces of piston and hollow cylinder; the center line of the torque which forces the piston to move within the hollow cylinder is an axis of the shaft of the single or double light collecting mirror; in the case of the single light collecting mirror, when the piston is fixedly connected to the framework of the light collecting mirror, the wall of the hollow cylinder is fixedly connected to the collecting carrier, or vice versa, i.e. when the piston is fixedly connected to the collecting carrier, the wall of the hollow cylinder is fixedly connected to the framework of the light collecting mirror; the chamber shock resist which rotates around the hinge shaft of the wind sheltering plate is installed in a manner that the hollow cylinder is fixedly connected to the wind sheltering plate when the piston is fixedly connected to the framework of the light collecting mirror, or vice versa, i.e. when the hollow cylinder is fixedly connected to the framework of the light collecting mirror, the piston is fixedly connected to the wind sheltering plate; in the case of the double light collecting mirror, the installment for the chamber shock resist which rotates around the hinge shaft of the main light collecting mirror is the same as the installment of the single light collecting mirror; the installment for the chamber shock resist which rotates around the hinge shaft of the auxiliary light collecting mirror is the same as the installment for the chamber shock resist around the hinge shaft of the wind sheltering plate of the single light collecting mirror, and
the elastic force shock resist is installed between the hinged member and the hinging member.

6. The highly efficient light collecting and superconductive generator according to claim 1, wherein the said uniform light device is a liquid lens or a solid lens located between the light collecting mirror and the light collecting cells, wherein the said liquid lens is a lens which consists of an inner transparent cover tube which surrounds the photovoltaic cells, an outer transparent cover tube and transparent medium between the cover tubes, and turns the collected light beam into an even intensity light beam, the layer between the inner transparent cover tube and the photovoltaic cells is a vacuum- or. negative pressure layer; the said solid lens is a cylindrical lens corresponding to a line focusing light collecting mirror, and turns the focused light beam into an even intensity light beam; or the solid lens is a lens corresponding to the point focusing light collecting mirror, and turns the focused light beam into an even intensity light beam.

7. The highly efficient light collecting and superconductive generator according to claim 6, wherein the liquid lens or solid lens is a lens corresponding to one of the line/area/point focusing light collecting mirror; the transparent cover tube corresponding to the point focusing light collecting mirror is called point light collecting cover tube that is in a form of group concave or group convex, and that along the length of the shell, at the inner or outer cover tube shell, or at both shells, there is one or two or three or four or five or six or seven or eight or nine rows of concave or convex hulls distributed, through which the sunlight passes during operation, with each row having a series of concave or convex hulls through which the focused light beam passes during operation; the transparent cover tube corresponding to the line focusing light collecting mirror is called line light collecting cover tube that is in a form of indentation or convex puncheon, and that along the length of the shell, at the inner or outer cover tube shell, or at both shells there is one or two, or three or four or five or six or seven or eight or nine rows of indentations or convex puncheons distributed, through which the focused light beam actually passes during operation; and the cross section thereof is any curve surface selected.

8. The highly efficient light collecting and superconductive generator according to claim 1, wherein the electromagnetic driving assembly fixedly connected to the wind-sheltering mechanism of the light collecting mirror comprises a wind sensor of an electric device, and further comprises a controller with a self-protection circuit against strong wind, the wind sensor, the controller and the electric device is in electromagnetic communication with each other, the electric device is connected to the object carrier of the automatic sun-tracking machine to transmit a torque.
